(19) United States
(12) Patent Application Publication
(10) Pub. No.: US 2008/0308952 A1
(43) Pub. Date: Dec. 18, 2008

(54) Method for Reliably Positioning Solder on a Die Pad for Attaching a Semiconductor Chip to the Die Pad and Molding Die for Solder Dispensing Apparatus

(75) Inventor: Yang Hong Heng, Muar Johor (MY)

Correspondence Address: DICKE, BILLIG & CZAJA, PLLC, FIFTH STREET TOWERS, 100 SOUTH FIFTH STREET, MINNEAPOLIS, MN, 55402, US

(73) Assignee: INFINEON TECHNOLOGIES AG, Neubiberg (DE)

(21) Appl. No.: 11/994,743

(22) PCT Filed: Jul. 28, 2005
(86) PCT No.: PCT/IB05/02227

§ 371 Date: Jun. 5, 2008

(51) Int. Cl. H01L 23/52; H01L 21/00

(52) U.S. Cl. 257/782; 438/121; 257/E23.141; 257/E21.001

(57) ABSTRACT

The rotational orientation of a die pad about its longitudinal axis is determined. The desired rotational orientation of a semiconductor chip to be attached to the die pad is determined. A molding die is provided which comprises a body with a cavity disposed in a bottom surface. The rotational orientation of the body of the molding die about its longitudinal axis is determined. The cavity is positioned in the body of the molding die with a rotational orientation such that the cavity is rotated with respect to the molding die by an angle corresponding to the desired rotational orientation of the semiconductor chip with respect to the die pad.

### CROSS-REFERENCE TO RELATED APPLICATIONS

This Utility patent application is a National Filing under 35 U.S.C. 371 of International Application No. PCT/IB2005/002227, filed Jul. 28, 2005, incorporated herein by reference.

### BACKGROUND

It is common practice to attach semiconductor chips, in particular power semiconductor chips, to the metallic die pad of a circuit carrier, such as a copper leadframe, by soft solder. The solder bond ensures that heat produced by the chip, while it is operating, can be more effectively dissipated by the die pad.

Typically, the solder is dispensed onto the die pad as a hemispherical mound and the semiconductor chip is pressed onto the solder deposit. It is also known to use a further pressing process to spread the solder deposit into a layer with a more uniform thickness by what is commonly referred to as a spanker or spanking tool. A layer of solder with a relatively uniform thickness increases the reliability of the bond between the semiconductor chip and the die pad since the chip is evenly coated by the solder and the formation of air bubbles at the interface can be avoided.

However, the lateral spread of the solder is unreliable so that either too large or too small an area is covered by the solder deposit. If solder spreads over the edges of the die pad. If the solder fails to cover the whole of the interface between the semiconductor chip and the die pad, the bond is unreliable.

In order to improve the reliability of the bonding process, it is known to more accurately control the quantity of solder deposited. However, the apparatus required to control the dispensing of the solder is complex and, therefore, relatively expensive. The problem of the inexact positioning of the pressed solder deposit on the die pad is also not completely eliminated.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a cross-sectional view of a molding die according to the invention.

FIG. 2 illustrates a perspective view of the bottom surface of the molding die of FIG. 1.

FIG. 3 illustrates an enlarged view of the bottom surface of the cross-sectional view of FIG. 1.

FIG. 4 illustrates an enlarged perspective view of the molding cavity of FIG. 2.

FIG. 5 illustrates the positioning of a solder deposit on a die pad using the molding die of FIGS. 1 to 4.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Embodiments of the invention provide a method for reliably positioning solder on a die pad for attaching a semiconductor chip to the die pad which includes the following processes. Firstly, the rotational orientation of the die pad about a longitudinal axis which lies essentially perpendicular to its upper surface is determined. The rotational orientation of the die pad about the longitudinal defines a first line. The upper surface of the die pad is defined here as the surface onto which a semiconductor chip will be mounted.

The desired rotational orientation about the first longitudinal axis with respect to the first line is determined for a semiconductor chip which is to be attached to the die pad. The semiconductor chip is rotated by an angle with respect to the first line.

A molding die which includes a body with a cavity is provided. The cavity is open on one side and disposed in a bottom surface of the body of the molding die. The body of the molding die has a second longitudinal axis lying essentially perpendicular to the bottom surface. The body of the molding die has a rotational orientation about the second longitudinal axis which defines a second line.

The cavity is positioned in the body of the molding die with a rotational orientation about the second longitudinal axis such that the cavity is rotated about the second longitudinal axis with respect to the second line by an angle corresponding to the rotational orientation of the semiconductor chip with respect to the first line. Angle is defined here as excluding an angle of 0°.

The molding die of the invention is adapted to be connected to solder dispensing apparatus, in particular a die bonder. The molding die of the invention is particularly suitable for use in the assembly of semiconductor packages in which the semiconductor chip is rotated with respect to the die pad of the leadframe substrate. The molding die according to the invention is adapted to be suitable for use when a semiconductor chip, when mounted on the die pad, is rotated about the longitudinal axis with respect to the die pad. In this arrangement, an edge of the semiconductor chip lies at an angle to the first line which defined by the rotational orientation of the die pad. This angle is defined here to be an angle other than 0° or 90°.

The molding die, therefore, includes a cavity which lies at a rotated angle with respect to the body of the molding die as indicated by the second line. This angle corresponds to the desired rotational angle of the semiconductor chip with respect to the first line defined by the rotational orientation of the die pad.

After a solder deposit is dispensed onto the die pad the shape and lateral spread of the deposit is modified by pressing the bottom surface of the body of the molding die onto the solder deposit. The molding tool is positioned with respect to the die pad so that the cavity is positioned over the solder deposit and the lateral spread of the solder deposit is controlled by the inner surfaces of the cavity. Therefore, the position of the solder deposit can be controlled during the pressing action and the position and, in particular, the rotational orientation of the pressed solder layer can be limited to the region onto which the semiconductor chip will be later mounted.

The semiconductor chip can, therefore, be mounted at the desired rotational angle essentially concentrically on the solder deposit which was positioned using the molding tool according to the invention. This limits the position of the solder deposit in the region of the interface between the semiconductor chip and the die pad and prevents the spread of the solder outside of the area occupied by the semiconductor chip.

The quantity of solder deposited can, therefore, be limited to the amount required to cover the interface between the semiconductor chip and the die pad. This reduces the materials costs. Since the solder deposit is positioned more exactly with respect to the desired position of the chip, the spread of the solder deposit onto areas of the die pad which are not covered by the semiconductor chip is limited. This has the advantage that the exposed areas of the die pad can be more reliably covered with an adhesion layer, such as a metal oxide. The adhesion between the die pad and the plastic encapsulation material which provides the housing of the package can, therefore, be improved.

To further improve the reliability of the solder bond and the reliability of the positioning of the solder deposit on the die pad, the following further processes may be performed. The lateral dimensions of the semiconductor chip are determined and the cavity provided with dimensions so that a solder deposit is produced which laterally corresponds to the lateral dimensions of the semiconductor chip. This further limits the positioning of the solder deposit to the region of the interface between the semiconductor chip and the die pad and further reduces the material usage.

The cavity can be provided with lateral dimensions which laterally fit within the die pad. This can result in the cavity having a lateral shape which does not correspond to the shape of the semiconductor chip. This can occur depending on the relative lateral size of the semiconductor chip and die pad and their rotational relationship.

If the die pad, the semiconductor chip and the cavity are laterally essentially rectangular, for example, two opposing corners of the cavity may be flattened to provide a cavity which, laterally, has a six-sided polygonal form. This ensures that the rotated solder deposit produced by the rotated cavity fits between the two long sides of the rectangular die pad.

In a further embodiment of the method, the body of the molding die may be laterally positioned with respect to the die pad such that the second line of the body lies in a plane parallel to the first line of the die pad. This further improves the positioning of the solder deposit on the die pad and limits the position to essentially the area which will be occupied by the semiconductor chip. The spread of the solder deposit outside of the interfacial area between the semiconductor chip and the die pad is, therefore, reduced.

The invention also provides a molding die for solder dispensing apparatus for attaching a semiconductor chip to a die pad. The molding die includes a body having a longitudinal axis lying essentially perpendicular to a bottom surface. The body has a rotational orientation about the longitudinal axis, which defines a line. The body of the molding die also includes a cavity which is open on one side and which is disposed in the bottom surface of the body. The cavity has a rotational orientation about the longitudinal axis and is rotated with respect to the line defined by the body of the molding die.

The molding die of the invention allows a solder deposit, which is positioned on the upper surface of a die pad, to be molded and positioned more accurately on the die pad with respect to the area occupied by the semiconductor chip. Therefore, the amount of solder which is dispensed can be reduced. The spread of the solder on to areas of the die pad which remain uncovered by the semiconductor chip can be largely prevented. This enables a more reliable application of an adhesion layer to the die pad. The improved adhesive layer further improves the adhesion of the plastic encapsulation material to the die pad. The risk of crack formation at the interface between the die pad and plastic molding material due to the large difference in thermal expansion coefficient is reduced. Therefore, the risk of water penetration into the package is reduced and the reliability of the package further increased.

The cavity can have side walls and a base, the base of the cavity lying in a plane essentially parallel to the bottom surface of the body. The side walls of the cavity can lie approximately perpendicular to the base. This provides a cavity which is able to mold the solder deposit so that the upper surface of the deposit lies approximately parallel to the upper surface of the die pad. This improves the interfacial bonding between the semiconductor chip and the die pad. If the side walls are essentially perpendicular to the base, the lateral spread of the solder is more easily controlled so that it remains essentially in the region occupied by the semiconductor chip.

The side walls define a lateral shape of the cavity. In an embodiment, the lateral shape is a six-sided polygon. In an embodiment, the polygon includes two right angled corners at opposing sides of the polygon which are linked by two inclined side walls. Inclined in this sense means that each of the two side walls has an internal angle of greater than 90° to the adjacent side wall of the right-angled corner.

The two inclined side walls lie essentially parallel to one another at opposing sides of the polygon. This enables the two inclined side walls to be aligned essentially parallel to two opposing edges of a square or rectangular die pad. The two right angled corners, therefore, extend towards the second opposing side walls of the die pad. This increases the size of the solder deposit which can be dispensed onto the die pad and, therefore, increases the size of the semiconductor chip which can be mounted on the die pad while limiting the position of the solder to the areas occupied by the semiconductor chip.

The perpendicular distance between the two inclined side walls is adapted, in an embodiment, to fit within the length of the die pad, the distance being smaller than the perpendicular distance between the two right angled corners. This lateral shape of the cavity is suitable for mounting a larger semiconductor chip, which is rotated with respect to the die pad, on a rectangular die pad.

The cavity further includes a recess positioned in its base. This can provide a molded solder deposit in which the lateral center of the molded layer has a greater thickness than the outer regions. This allows the solder deposit to laterally spread as the semiconductor chip is pressed onto the solder deposit. Therefore, the thickness of the deposit after the semiconductor chip has been mounted, is more uniform across the area occupied by the chip.

The recess has, in an embodiment, lateral dimensions of approximately half of the lateral dimensions of the cavity at the bottom surface. This provides a more uniform solder thickness after the mounting of the semiconductor die and additional lateral spreading of the solder deposit.

The recess may be laterally rectangular. This is the semiconductor chip is laterally rectangular as the position and spread of the solder is more closely matched to the shape of the semiconductor chip.

Two opposing corners of the recess may be concentrically disposed with respect to the two right angled corners of the six sided polygon of the cavity. This further improves the positioning of the solder deposit with respect to the semiconductor chip.

The line defining the rotational orientation of the body may be adapted to be parallel to a side edge of a die pad. The cavity is, therefore, rotated about the longitudinal axis with respect to the edge of the die pad. This simplifies the alignment of the molding die with respect to the die pad. This further improves the positioning of the solder deposit on the die pad and prevents spreading of the solder over the edges of the die pad.

The body of the molding die further includes means for attaching the body of the molding die to solder dispensing apparatus. Therefore, the molding die of the invention can be used with existing solder dispensing apparatus. This reduces the start up costs and simplifies the use of the molding die within the existing manufacturing line. The molding die includes material which is not wetted by solder. This prevents the adhesion of the molding die to the solder and improves the reliability of the process.

The invention, therefore, provides a method for reliably positioning solder on a die pad which enables a semiconductor chip to be reliably attached to the die pad. This is achieved by positioning the solder deposit such that the rotational orientation of the molded solder deposit on the die pad corresponds to the rotational orientation of the semiconductor chip on the die pad. This enables the quantity of solder deposited to be reduced.

The solder deposit is more reliably positioned so as to be largely disposed at the interface between the semiconductor chip and the die pad. Therefore, the exposed regions of the die pad remain free from solder. This enables an adhesion layer, such as a metal oxide layer, to be more reliably deposited or grown on the exposed regions of the die pad. Therefore, the adhesion between the die pad an plastic encapsulation is improved and the reliability of the package is further improved.

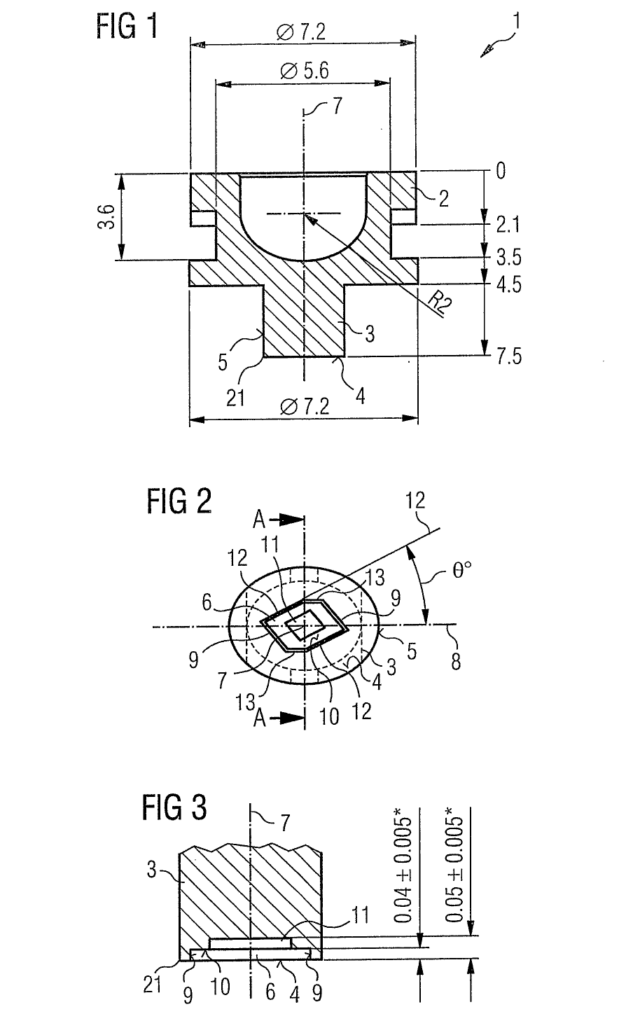

FIG. 1 illustrates a cross-sectional view of a molding die 1 according to embodiments of the invention. The molding die 1 is also known as a spanker or spanking tool. The same reference numbers are used in all of the diagrams to denote the same feature.

The molding die 1 includes an upper portion 2 which is adapted to be attachable to solder dispensing apparatus. In this embodiment of the invention, the upper portion includes a domed-shape cavity. However, the upper portion 2 may be provided with any means such as lugs or with a size so as to be connectable to the solder dispensing apparatus, which is, in particular, a die bonder suitable for the attachment of semiconductor chips to a metal die pad. The lower portion 3 of the molding die 1 includes the body of the molding die 1 and includes, in this embodiment, a protruding cylinder with a bottom surface 4 and side surface 5.

The bottom surface 4 provides the molding surface of the molding die 1. As can be seen in FIGS. 2 and 3, the bottom surface 4 of the molding die 1 includes a cavity 6. The cavity 6 has the form of a depression which is positioned in the bottom surface 4 of the molding die 1 and which is open on one side, i.e. the bottom surface 4. The molding die 1 has a longitudinal axis 7 which is essentially perpendicular to the bottom surface 4.

The edge 21 between the bottom surface 4 of the protruding cylinder 3 and its side surface 5 is sharp. In order to mold the deposited solder, the bottom surface 4 of the molding die 1 is lowered downwards onto a solder deposit which is positioned on a die pad. The cavity 6 molds or shapes the solder deposit and limits the lateral spread of the deposit to the area within the lateral area of the cavity 6. Therefore, the sharp edge between the bottom surface 4 and the side wall 5 of the lower portion 3 of the molding die 1 ensures that the molding die 1 makes a reliable contact to the die pad and prevents the spread of the solder outside of the molding die 1.

FIG. 2 illustrates a perspective view of the bottom surface 4 of the molding die 1 of FIG. 1 including the cavity 6. The longitudinal axis 7 of the molding die 1 is, therefore, represented by the point in the lateral center of the bottom surface 4. The molding die 1 has a rotational orientation about the longitudinal axis 7 which is defined and, indicated in FIG. 2, by a line 8. In the view of FIG. 2, the line 8 lies approximately horizontally.

As can be seen in conjunction with the enlarged cross-sectional view of FIG. 3, the cavity 6 is essentially rectangular and is positioned in approximately the lateral center of the bottom surface 4 of the molding die 1. The cavity 6 includes side walls 9 and a base 10. The base 10 lies in a plane essentially parallel to the bottom surface 4 of the molding tool 1. The side walls 9 lie essentially perpendicular to the base 10 and the bottom surface 4 of the molding tool 1.

The perspective view of the bottom surface 4 illustrated in FIG. 2, illustrates that the cavity 6 is rotated around the longitudinal axis 7 with respect to the rotational orientation of the moulding die 1 as defined by the line 8. The long side 12 of the cavity 6 lies at an angle, illustrated in the diagram as θ°, to the line 8 which defines the rotational orientation of the body 3 of the molding die 1. The angle θ° has a value of between approximately 2° to approximately 88° or, in some embodiments, between approximately 2° to approximately 40°, or more in other embodiments, between approximately 15° to approximately 25°.

In the embodiment illustrated in FIG. 2, two opposing corners of the cavity 6 include a chamfer 13. Therefore, the cavity 6 has the lateral form of a six sided polygon. The two chamfered edges or inclined sides 13 lie in a plane essentially parallel to the first line 8 which defines the rotational orientation of the molding die 1.

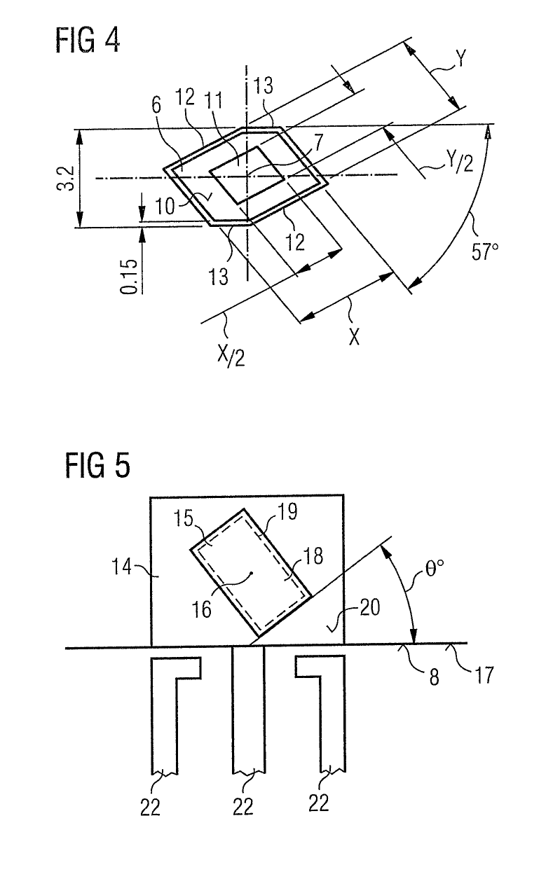

The cavity 6 also includes a recess 11 positioned in approximately the lateral center of the base 10, as illustrated in the enlarged view of cross-sectional view of the bottom surface 4 of FIG. 3. The recess is also rectangular and has lateral dimensions of approximately half the lateral dimensions of the cavity 6 defined by the edge of the side walls 8 with the bottom surface 4 of the molding die 1. The dimensions of an embodiment are indicated in the enlarged view of FIG. 4. The recess 11 is positioned concentrically with respect to the long side walls 12 of the cavity 6. Therefore, the long side of the recess 11 also lies at an angle θ° with respect to the line 8 defined by the molding die 1. In this embodiment, the dimension x is 2.97 mm and the dimension y is 2.47 mm. The rectangular recess 11 has lateral dimensions of 1.485 mm and 1.235 mm.

FIG. 5 illustrates a schematic diagram of a die pad 14 including a solder deposit 15 which was molded using the molding die 1 of FIGS. 1 to 4.

The die pad 14 is part of a leadframe suitable for a power transistor which includes the die pad 14 and three leads or pins 22 which are positioned on one side of the die pad 14. The die pad 14 is essentially rectangular with its long side lying essentially horizontally as illustrated in the view of FIG. 5. The die pad 14 also has a longitudinal axis 16 which lies essentially perpendicular to the upper surface of the die pad 14. This is indicated by the point 16 positioned in approximately the lateral center of the die pad 14. The die pad 14 has a rotational orientation about the axis 16 which is defined and is indicated by a line 17. In the view of FIG. 5, the line 17 lies essentially parallel to the long edge of the die pad 14.

A solder deposit was dispensed on to approximately the center of the die pad 14. The molding die 1 was rotationally orientated so that its rotational orientation, as indicated by the line 8 lay parallel to the rotational orientation of the die pad 14 has indicated by the line 17. Therefore, the orientation between the solder deposit 15 and the die pad 14 corresponds to the orientational relationship between the cavity 6 and the molding die 1 as illustrated in FIGS. 1 to 4. The molding die 1 of FIGS. 1 to 4 was then pressed down onto the solder deposit 15. Therefore, the molded solder deposit 15 has the approximate dimensions of the cavity 6 and lies at a rotational angle of θ to the line 17 defining the rotational orientation of the die pad 14.

The desired position of the semiconductor chip 18 is indicated by the dotted line 19, as can be seen in FIG. 5. The solder deposit 15 is, therefore, molded so as to be essentially concentric with the desired position of the semiconductor chip 18.

A method to more reliably position the solder deposit 15 on the die pad 14 includes the following processes. Firstly, the rotational orientation of the die pad 14 about the longitudinal axis 16 is defined and, in this case, is indicated by the line 17. The desired rotational orientation of the semiconductor chip 18 with respect to the longitudinal axis 16 is then determined. The semiconductor chip should be rotated with respect to the line 17, defining the rotational orientation of the die pad 14, by approximately θ°.

A molding die 1 including a cavity 6 is provided. The body of the molding die 1 has a longitudinal axis 7 which is perpendicular to its bottom surface 4. The rotational orientation of the molding die 1 about the longitudinal axis 7 is determined and defines a line which is indicated in the figures by a line 8.

The position of the cavity 6 disposed in the lower surface 4 of the molding die 1 is then provided such that the rotational orientation of the cavity 6 with respect to the orientational orientation of the molding die 1 corresponds to the desired rotational relationship between the semiconductor chip and the die pad 14. Therefore, the cavity 6 lies at a rotational angle of θ° to the defined rotational orientation of the molding die 1 indicated by the line 8.

Therefore, after the solder deposit 15 is positioned in approximately the lateral center of the die pad 14, the molding die 1 is rotationally orientated so that it is essentially in the same rotational orientation as the die pad 14. In this embodiment, the lines 8 and 17 indicating the rotational orientation of the molding die 1 and die pad 14 lie essentially parallel to one another. The respective longitudinal axes 7, 16 of the molding die 1 and die pad 14, therefore, lie in essentially parallel planes. The molding die 1 is then pressed onto the solder deposit, the solder deposit 15 spreads and its lateral dimensions are controlled by the cavity 6. Therefore, the solder deposit 15 on the die pad can be reliably positioned so that it is concentric with the desired position of the semiconductor chip 18.

The semiconductor chip 18 is then pressed onto the molded deposit 15. The electrical connections between the semiconductor chip 18 and leads 22 of the package, which are not illustrated in FIG. 5, are then produced by bond wires. The areas 20 of the die pad which remain uncovered by solder are coated by a metal oxide adhesion layer. The die pad 14, semiconductor chip 18 and bond wires are encapsulated in plastic material to form the package.

By controlling the position of the solder using the method of the invention, the remaining exposed areas 20 of the die pad 14 can be reliably coated with an adhesive layer which promotes the adhesion between the plastic encapsulation material and the die pad. The risk of crack formation at the interface between the die pad 14 and the plastic molding or encapsulation material is, therefore, reduced and water penetration into the package can be avoided. The reliability of the package can, therefore, be improved.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

1-15. (canceled)

16. A method for positioning solder on a die pad for attaching a semiconductor chip to the die pad, the method comprising:
determining a rotational orientation of the die pad about a first longitudinal axis perpendicular to an upper surface of the die pad, the rotational orientation defining a first line;
determining a desired rotational orientation of a semiconductor chip to be attached to the die pad about the first longitudinal axis with respect to the first line, the semiconductor chip being rotated with respect to the first line by an angle;
providing a molding die comprising a body with a cavity open on one side and disposed in a bottom surface, the body of the molding die having a second longitudinal axis lying perpendicular to the bottom surface and a rotational orientation about the second longitudinal axis defining a second line, and
positioning the cavity in the body of the molding die with a rotational orientation about the second longitudinal axis such that the cavity is rotated about the second longitudinal axis with respect to the second line by an angle corresponding to the rotational orientation of the semiconductor chip with respect to the first line.

17. The method of claim 16, further comprising:
determining lateral dimensions of the semiconductor chip;
dimensioning the cavity to provide a solder deposit which laterally corresponds to the lateral dimensions of the semiconductor chip.

18. The method of claim 17, further comprising:
providing the cavity with lateral dimensions which laterally fit within the die pad.

19. The method of claim 16 further comprising:
aligning the body of the molding die with respect to the die pad such that the second line of the body lies in a plane parallel to the first line of the die pad.

20. A molding die for solder dispensing apparatus for attaching a semiconductor chip to a die pad, the molding die comprising:
a body having a longitudinal axis lying perpendicular to a bottom surface of the body;
the body having a rotational orientation about the longitudinal axis;
the rotational orientation defining a line, wherein the body includes a cavity open on one side, the cavity being disposed in the bottom surface of the body, wherein the cavity has a rotational orientation about the longitudinal axis and is rotated with respect to the line.

21. The molding die of claim 20, wherein the cavity has side walls and a base, wherein the base of the cavity lies in a plane essentially parallel to the bottom surface of the body, and wherein the side walls of the cavity are approximately perpendicular to the base.

22. The molding die of claim 20, wherein the side walls define a lateral shape of the cavity, wherein the lateral shape is a six-sided polygon.

23. The molding die of claim 22, wherein the polygon includes two right angled corners at opposing sides of the polygon linked by two inclined side walls lying essentially parallel to one another at opposing sides of the polygon.

24. The molding die of claim 23, wherein the perpendicular distance between the two inclined side walls is adapted to fit within the length of the die pad, the distance being smaller than the perpendicular distance between the two right angled corners.

25. The molding die of claim 20, wherein the cavity further has a recess positioned in its base.

26. The molding die of 25, wherein the recess has lateral dimensions of approximately half of the dimensions of the cavity at the bottom surface of the body of the molding die.

27. The molding die of claim 25, wherein the recess is laterally rectangular.

28. The molding die of claim 25, wherein two opposing corners of the recess are concentrically disposed with respect to the two right angled corners of the six sided polygon of the cavity.

29. The molding die of claim characterized in that the line defining the rotational orientation of the body is adapted to be parallel to a side edge of a die pad and the cavity is rotated about the longitudinal axis with respect to the edge of the die pad.

30. The molding die of claim 20, wherein the body of the molding die is attachable to solder dispensing apparatus.
